(19) United States
(12) Patent Application Publication
(10) Pub. No.: US 2014/0154833 A1
(43) Pub. Date: Jun. 5, 2014

(54) MANUFACTURING METHOD FOR DETECTION APPARATUS

(71) Applicant: CANON KABUSHIKI KAISHA, Tokyo (JP)

(72) Inventors: Hiroshi Wayama, Saitama-shi (JP); Minoru Watanabe, Honjo-shi (JP); Keigo Yokoyama, Honjo-shi (JP); Masato Ofuji, Honjo-shi (JP); Jun Kawanabe, Kumagaya-shi (JP); Kentaro Fujiyoshi, Tokyo (JP)

(73) Assignee: CANON KABUSHIKI KAISHA, Tokyo (JP)

(21) Appl. No.: 14/085,993

(22) Filed: Nov. 21, 2013

(30) Foreign Application Priority Data
Dec. 3, 2012 (JP) 2012-264741

(51) Int. Cl. H01L 27/146

(52) U.S. Cl. CPC H01L 27/14605
USPC 438/80

(57) ABSTRACT

A manufacturing method for a detection apparatus is provided. The method includes depositing a first impurity semiconductor layer and a first intrinsic semiconductor layer in this order on a plurality of first electrodes arranged in an array above a substrate. The method also includes patterning the first intrinsic semiconductor layer and the first impurity semiconductor layer and thereby dividing the first intrinsic semiconductor layer and the first impurity semiconductor layer so as to cover each of the plurality of first electrodes separately. The method further includes depositing a second intrinsic semiconductor layer on the patterned first intrinsic semiconductor layer.

### BACKGROUND OF THE INVENTION

1. Field of the Invention

The present disclosure relates to a manufacturing method for a detection apparatus.

2. Description of the Related Art

In recent years, manufacturing technology for a liquid crystal panel using thin-film transistors (TFTs) has been used for a detection apparatus. In such a detection apparatus, aperture ratio improvements are achieved by forming conversion elements at locations where TFTs are covered. The conversion element has a PIN structure in which, for example, a p-type semiconductor layer, intrinsic semiconductor layer, and n-type semiconductor layer are accumulated and the intrinsic semiconductor layer functions as a photoelectric conversion layer. To improve quantity of charge and SNR, U.S. Pat. No. 5,619,033 proposes a detection apparatus which realizes an aperture ratio of 100% by forming a photoelectric conversion layer over an entire pixel array and placing electrodes adapted to collect the charge generated by the photoelectric conversion layer, on a pixel by pixel basis. According to U.S. Pat. No. 5,619,033, to manufacture the detection apparatus, after discrete electrodes are formed, an impurity semiconductor layer is deposited, covering the discrete electrodes. Subsequently, the impurity semiconductor layer is patterned and divided on a pixel by pixel basis and the intrinsic semiconductor layer is deposited on the patterned impurity semiconductor layer.

### SUMMARY OF THE INVENTION

The manufacturing method described in U.S. Pat. No. 5,619,033 has the following problem. Generally, the impurity semiconductor layer which constitutes the conversion elements is a few tens of nm in film thickness, and thus there is a possibility that the impurity semiconductor layer may peel off in an etching process for patterning the impurity semiconductor layer. Thus, an aspect of the present invention provides a technique advantageous for a detection apparatus in which a photoelectric conversion layer is formed over an entire pixel array.

According to some embodiments, a manufacturing method for a detection apparatus is provided. The method includes depositing a first impurity semiconductor layer and a first intrinsic semiconductor layer in this order on a plurality of first electrodes arranged in an array above a substrate. The method also includes patterning the first intrinsic semiconductor layer and the first impurity semiconductor layer and thereby dividing the first intrinsic semiconductor layer and the first impurity semiconductor layer so as to cover each of the plurality of first electrodes separately. The method further includes depositing a second intrinsic semiconductor layer on the patterned first intrinsic semiconductor layer.

Further features of the present invention will become apparent from the following description of exemplary embodiments (with reference to the attached drawings).

### BRIEF DESCRIPTION OF THE DRAWINGS

FIG. 1 is a diagram describing an example of overall configuration of a detection apparatus according to an embodiment of the present invention.

FIGS. 2A and 2B are diagrams describing a detailed configuration example of the detection apparatus according to the embodiment of the present invention.

FIGS. 3A to 3I are diagrams describing an example of a manufacturing method for the detection apparatus according to the embodiment of the present invention.

FIG. 4 is a diagram describing a natural oxide film produced in the detection apparatus according to the embodiment of the present invention.

FIG. 5 is a diagram describing the background for another example of the manufacturing method for the detection apparatus according to the embodiment of the present invention.

FIGS. 6A to 6D are diagrams describing other examples of the manufacturing method for the detection apparatus according to the embodiment of the present invention.

FIG. 7 is a diagram describing a configuration of a radiation detection system according to the embodiment of the present invention.

### DESCRIPTION OF THE EMBODIMENTS

Embodiments of the present invention will be described below in detail with reference to the accompanying drawings. Throughout various embodiments, similar components are denoted by the same reference numerals, and redundant description thereof will be omitted. Also, each embodiment can be changed as appropriate, and different embodiments can be used in combination. Generally the present invention is applicable to a detection apparatus in which a conversion layer is formed over a pixel array containing plural pixels. Conversion elements of a PIN structure will be described below by way of example, but conversion elements of a NIP structure with an opposite conductivity type may be used alternatively. Similarly, bottom-gate thin-film transistors will be described below by way of example, but top-gate thin-film transistors may be used alternatively. The transistors may be made of either amorphous silicon or polysilicon. Also, electromagnetic waves herein range from those in the wavelength region of light to those in the wavelength region of radiation and include visible to infrared light rays as well as radiation such as x-rays, alpha rays, beta rays, and gamma rays.

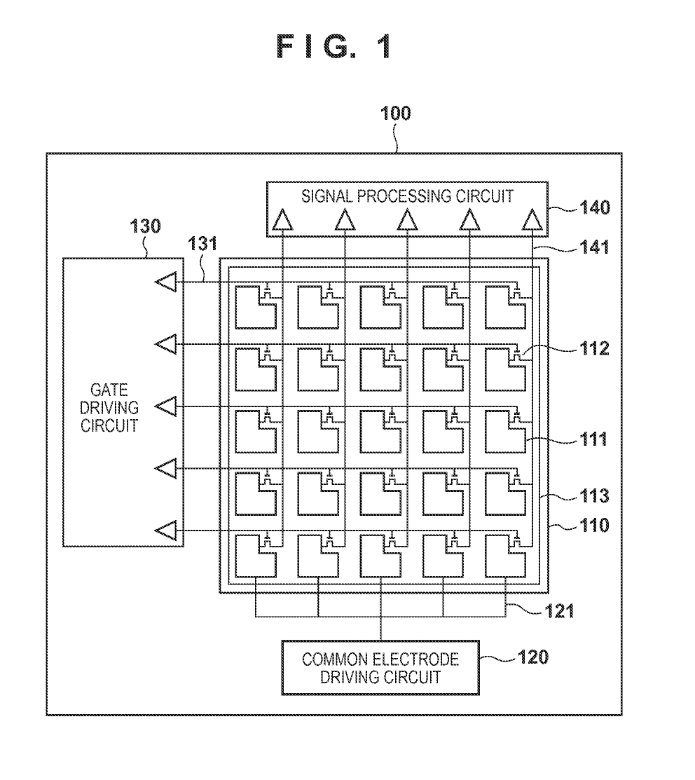

An overall configuration of a detection apparatus 100 according to some embodiments of the present invention will be described with reference to FIG. 1. The detection apparatus 100 includes a pixel array 110, a common electrode driving circuit 120, a gate driving circuit 130, and a signal processing circuit 140. The pixel array 110 has plural pixels arranged in an array. The pixel array 110 has, for example, about 3000 rows by 3000 columns of pixels, but is shown as having 5 rows by 5 columns of pixels in FIG. 1 for purposes of explanation.

Each pixel includes a conversion element 111 and a transistor 112. The conversion element 111 generates a charge corresponding to electromagnetic waves received by the detection apparatus 100. The conversion element 111 may be a photoelectric conversion element adapted to convert visible light, converted from radiation by a scintillator, into a charge or may be a conversion element adapted to convert radiation directed at the detection apparatus 100 directly into a charge. The transistor 112 is, for example, a thin-film transistor. The conversion element 111 and a first main electrode (source or drain) of the transistor 112 are electrically connected to each other. Although the conversion element 111 and transistor 112 are illustrated in FIG. 1 as being adjacent to each other in a direction parallel to a substrate surface, the conversion element 111 and transistor 112 are placed by overlapping each other in a direction perpendicular to the substrate surface as described later. The pixel array 110 further includes a common electrode 113 placed commonly to plural pixels.

The common electrode driving circuit 120 is connected to the common electrode 113 via a driving line 121 and adapted to control a drive voltage supplied to the common electrode 113. The gate driving circuit 130 is connected to a gate of the transistor 112 through a gate line 131 and adapted to control conduction of the transistor 112. The signal processing circuit 140 is connected to a second main electrode (drain or source) of the transistor 112 via a signal line 141 and adapted to read a signal out of the conversion element 111.

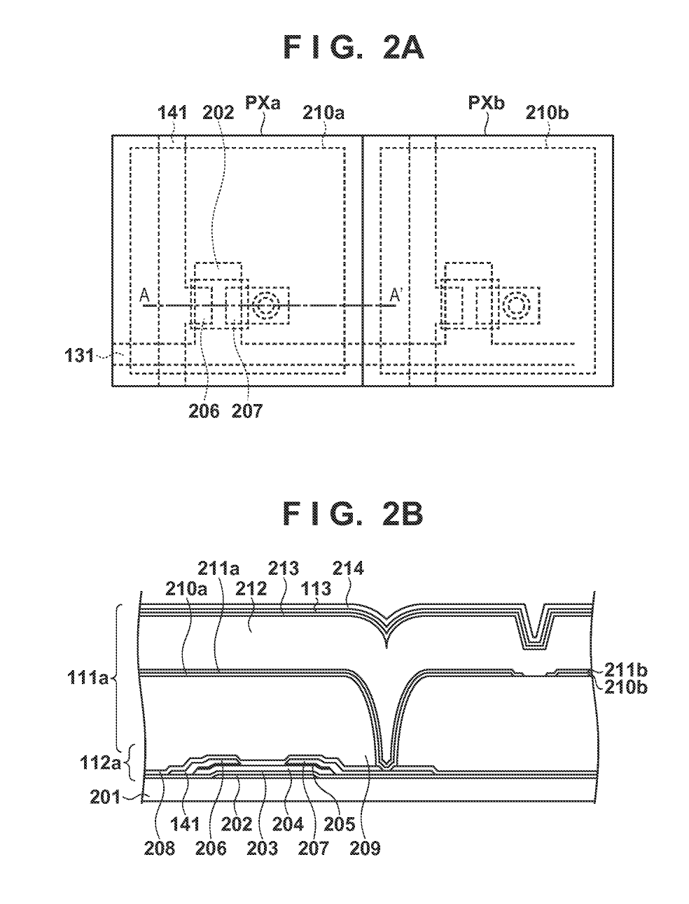

Next, a detailed configuration of the pixels of the detection apparatus 100 will be described with reference to FIGS. 2A and 2B. FIG. 2A is a plan view focusing on two adjacent pixels PXa and PXb contained in the pixel array 110 while FIG. 2B is a sectional view taken along line A-A′ in FIG. 2A. Every pixel of the pixel array 110 may have a same configuration, and thus a configuration of the pixel PXa will mainly be described below.

The pixel array 110 is placed on a substrate 201, and each pixel in the pixel array 110 has a conversion element 111 and transistor 112. The pixel PXa includes a conversion element 111a as the conversion element 111, and a transistor 112a as the transistor 112. The transistor 112a includes a gate electrode 202, an insulating layer 203, an intrinsic semiconductor layer 204, an impurity semiconductor layer 205, a first main electrode 206, and a second main electrode 207. The gate electrode 202 is provided separately for each pixel. The insulating layer 203 is formed over the pixel array 110, covering the gate electrodes 202 of each of the pixels. That part of the insulating layer 203 which covers the gate electrode 202 functions as a gate insulating film of the transistor 112a. The intrinsic semiconductor layer 204 is provided separately for each pixel at such a location as to cover the gate electrode 202 via the insulating layer 203. A channel of the transistor 112a is formed in the intrinsic semiconductor layer 204. One end of the first main electrode 206 is placed on the intrinsic semiconductor layer 204 via the impurity semiconductor layer 205, and the other end is connected to the signal line 141. One end of the second main electrode 207 is placed on the intrinsic semiconductor layer 204 via the impurity semiconductor layer 205, and the other end extends outside the intrinsic semiconductor layer 204. The impurity semiconductor layer 205 reduces contact resistance between the intrinsic semiconductor layer 204 and the first and second main electrodes 206 and 207.

The detection apparatus 100 further includes a protective layer 208 formed over the pixel array 110, covering the transistors 112. The protective layer 208 has an opening to expose part of the second main electrode 207. A planarizing layer 209 is formed on the protective layer 208, spreading over the pixel array 110. The planarizing layer 209 has an opening adapted to expose the opening in the protective layer 208 and consequently expose part of the second main electrode 207. The planarizing layer 209 enables stable formation of the conversion element 111a and allows reduction of parasitic capacitance between the transistor 112a and conversion element 111a.

The detection apparatus 100 includes a discrete electrode 210a, an n-type semiconductor layer 211a, an intrinsic semiconductor layer 212, a p-type semiconductor layer 213, and a common electrode (the second electrode) 113 in order of increasing distance from the substrate 201, making up the conversion element 111a. That is, the conversion element 111a has a PIN structure. Both discrete electrode 210a (first electrode) and n-type semiconductor layer (first impurity semiconductor layer) 211a are provided separately for each pixel. The intrinsic semiconductor layer 212, p-type semiconductor layer 213 (second impurity semiconductor layer), and common electrode (second electrode) 113 are formed over the pixel array 110. The discrete electrode 210a is put in contact with the second main electrode 207 of the transistor 112a through the opening in protective layer 208 and opening in the planarizing layer 209, thereby electrically connecting the discrete electrode 210a and transistor 112a to each other. The intrinsic semiconductor layer 212 functions as a conversion layer and generates a charge corresponding to received electromagnetic waves. The charge generated by that part of the intrinsic semiconductor layer 212 which covers the discrete electrode 210a is collected by the discrete electrode 210a. The detection apparatus 100 further includes a protective layer 214 formed over the pixel array 110, covering the conversion elements 111.

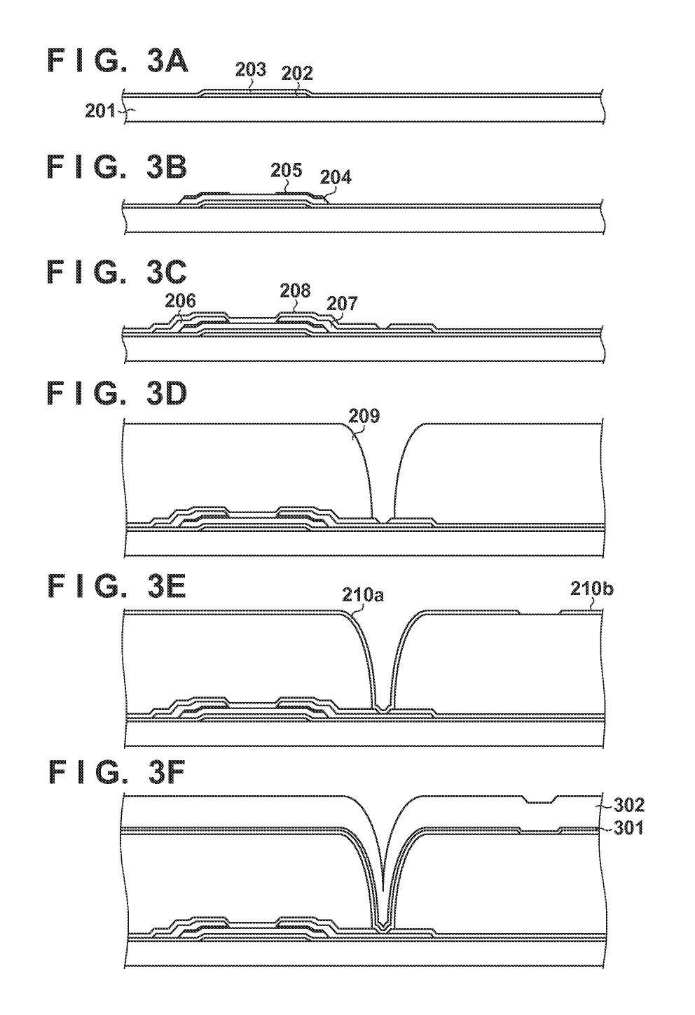

Next, an example of a manufacturing method for the detection apparatus 100 will be described with reference to FIGS. 3A to 3I. FIGS. 3A to 3I are sectional views corresponding to the sectional view of FIG. 2B and to individual manufacturing processes. First, as shown in FIG. 3A, the gate electrode 202 of the transistor 112 is formed on the substrate 201, and the insulating layer 203 is deposited thereon. The gate electrode 202 is formed, for example, by patterning a metal layer deposited on the entire surface of the substrate 201 by a sputtering machine. The metal layer is, for example, 150 nm to 700 nm thick and is made of a low-resistance metal such as Al, Cu, Mo, or W; or an alloy or laminate thereof. The insulating layer 203 is made, for example, of silicon nitride film (SiN). The film thickness of the insulating layer 203 is set, for example, to 150 nm to 600 nm to increase capacity of the gate insulating film while maintaining a breakdown voltage of the transistor 112, for example, at around 200 V.

Next, as shown in FIG. 3B, the intrinsic semiconductor layer 204 is formed on the insulating layer 203, and the impurity semiconductor layer 205 is formed thereon. The intrinsic semiconductor layer 204 is formed by etching a deposited intrinsic semiconductor layer in an island pattern. The intrinsic semiconductor layer 204 is set to be, for example, 100 nm to 250 nm thick so as to reduce series resistance of the transistors 112 and so as to be thick enough not to be removed by etching when the impurity semiconductor layer 205 is formed. The impurity semiconductor layer 205 is formed by etching a deposited impurity semiconductor layer in an island pattern and then removing a central portion (portion covering a channel area) thereof. The impurity semiconductor layer 205 may have any thickness as long as junction between the intrinsic semiconductor layer 204 and the first and second main electrodes 206 and 207 is allowed for, and may be, for example, 20 nm to 70 nm thick.

Next, as shown in FIG. 3C, the signal line 141, first main electrode 206, and second main electrode 207 are formed, and then the protective layer 208 is formed thereon. The signal line 141, first main electrode 206, and second main electrode 207 are formed, for example, by patterning a metal layer deposited on the entire surface of the substrate 201 by a sputtering machine. The metal layer is, for example, 150 nm to 800 nm thick and is made of a low-resistance metal such as Al, Cu, Mo, or W; or an alloy or laminate thereof. The protective layer 208 is formed by depositing an insulating layer on the entire surface of the substrate 201 and then removing part of the insulating layer so as to expose part of the second main electrode 207. The film thickness of the protective layer 208 is, for example, 200 nm to 500 nm.

Next, the planarizing layer 209 is formed as shown in FIG. 3D. The planarizing layer 209 is formed by depositing an organic layer on the entire surface of the substrate 201 and then removing part of the organic layer so as to expose the opening in the protective layer 208. The planarizing layer 209 is configured to be, for example, 1 μm to 5 μm in film thickness so as to achieve the function of the planarizing layer 209 described above.

Next, the discrete electrodes 210a and 210b are formed as shown in FIG. 3E (first electrode forming process). The discrete electrodes 210a and 210b are formed, for example, by patterning a metal layer deposited on the entire surface of the substrate 201. The discrete electrodes 210a and 210b may be transparent electrodes made of ITO or the like, and can be configured to be about a few tens of nm in thickness in that case. Alternatively, the discrete electrodes 210a and 210b may be made of a low-resistance metal such as Al, Cu, Mo, or W; or an alloy or laminate thereof, and can be configured to be, for example, about 50 nm to 300 nm thick in that case.

Next, as shown in FIG. 3F, an n-type semiconductor layer 301 is formed on the entire surface of the substrate 201, and then an intrinsic semiconductor layer 302 (first intrinsic semiconductor layer) is formed thereon, covering the entire surface of the substrate 201 (first film deposition process). The n-type semiconductor layer 301 and intrinsic semiconductor layer 302 are deposited by the same deposition apparatus (e.g., CVD apparatus) without exposure to the atmosphere. First, the substrate 201 subjected to the process of FIG. 3E is set up in the deposition apparatus, and the n-type semiconductor layer 301 is deposited to a thickness of, for example, 10 nm to 100 nm. Subsequently, the gas is changed, with the substrate 201 kept in the deposition apparatus, and the intrinsic semiconductor layer 302 is deposited to a thickness of, for example, 30 nm to 100 nm.

Next, as shown in FIG. 3G, the n-type semiconductor layer 301 and intrinsic semiconductor layer 302 are patterned, and a portion covering portions free of the discrete electrodes 210a and 210b is removed. Consequently, the n-type semiconductor layer 301 is divided into pixel-by-pixel, n-type semiconductor layers 211a and 211b.

Next, as shown in FIG. 3H, an intrinsic semiconductor layer 303 (second intrinsic semiconductor layer) is formed on the entire surface of the substrate 201, and then the p-type semiconductor layer 213 is formed thereon, covering the entire surface of the substrate 201 (second film deposition process). The intrinsic semiconductor layer 303 and p-type semiconductor layer 213 are deposited by the same deposition apparatus (e.g., CVD apparatus) without exposure to the atmosphere. First, the substrate 201 subjected to the process of FIG. 3G is set up in the deposition apparatus, and the intrinsic semiconductor layer 303 is deposited to a thickness of, for example, 300 nm to 2000 nm on the patterned intrinsic semiconductor layer 302. Subsequently, the gas is changed, with the substrate 201 kept in the deposition apparatus, and the p-type semiconductor layer 213 is deposited to a thickness of, for example, about a few tens of nm. The two intrinsic semiconductor layers 302 and 303 described above make up the intrinsic semiconductor layer 212 of FIGS. 2A and 2B.

Next, as shown in FIG. 3I, the common electrode 113 is formed (second electrode forming process), and then the protective layer 214 is formed thereon, covering the entire surface of the substrate 201. The common electrode 113 is formed, for example, by depositing a metal layer on the entire surface of the substrate 201. The common electrode 113 may be a transparent electrode made of ITO or the like, and can be configured to be about a few tens of nm thick in that case. Alternatively, the common electrode 113 may be made of a low-resistance metal such as Al, Cu, Mo, or W; or an alloy or laminate thereof, and can be configured to be, for example, about 300 nm to 700 nm thick in that case. The protective layer 214 is formed, for example, by depositing an insulating layer on the entire surface of the substrate 201. Subsequently, the detection apparatus 100 having a sectional structure shown in FIG. 2B is produced, for example, by forming remaining components by a known method.

The intrinsic semiconductor layer 212 is deposited by being divided into the intrinsic semiconductor layer 302 and intrinsic semiconductor layer 303 in a manner such as described above, and then the n-type semiconductor layer 301 and intrinsic semiconductor layer 302 are deposited by the same deposition apparatus without exposure to the atmosphere. This curbs generation of a natural oxide film on the surface of the n-type semiconductor layer 301. This in turn curbs degradation of junction between the n-type semiconductor layer 301 and intrinsic semiconductor layer 302. Also, if the n-type semiconductor layer 301 is patterned after being deposited, the n-type semiconductor layer 301 may peel off because of the small film thickness. However, when patterning is done after the n-type semiconductor layer 301 and intrinsic semiconductor layer 302 are deposited as with the above method, since the total film thickness of these layers is at least 30 nm, peeling is less likely to occur.

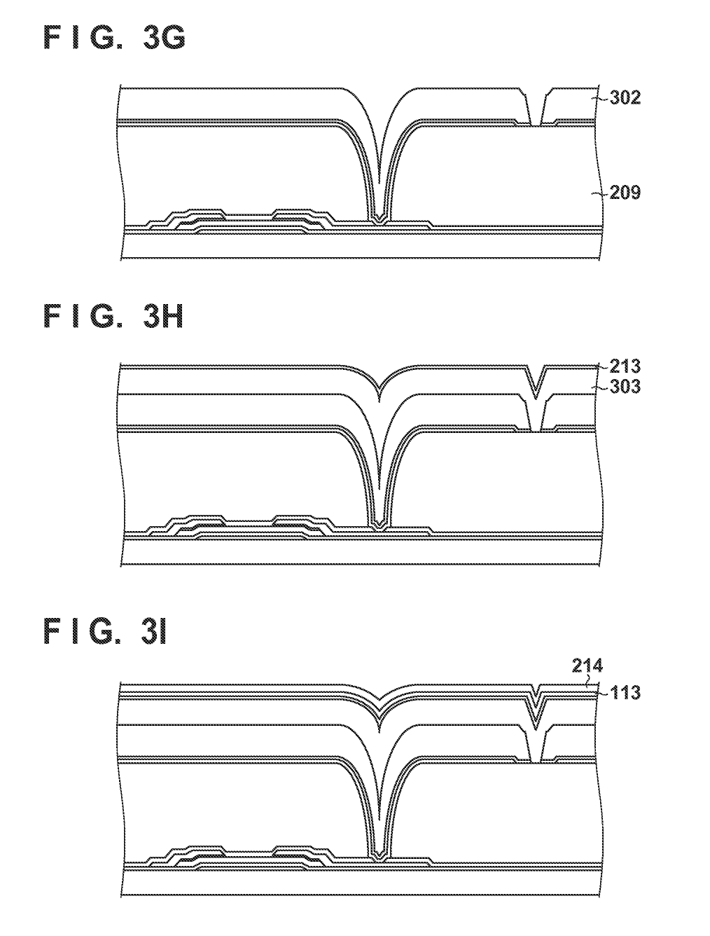

When the n-type semiconductor layer 301 and intrinsic semiconductor layer 302 are patterned, a natural oxide film 401 (FIG. 4) is produced on the surface of the intrinsic semiconductor layer 302. However, since an oxidation rate of the intrinsic semiconductor layer is generally smaller than an oxidation rate of the n-type semiconductor layer, the film thickness of the natural oxide film can be reduced compared to when a natural oxide film is produced on the surface of the n-type semiconductor layer 301, and consequently junction resistance can be reduced. Furthermore, because the natural oxide film 401 formed on the intrinsic semiconductor layer 302 is located away from the discrete electrode 210a, when, for example, the charge accumulated by photoelectric conversion is transferred to the transistor 112a, the influence on a neighborhood of the electrode on which the charge is accumulated is reduced. To keep the natural oxide film 401 away from both the discrete electrode 210a and common electrode 113, the n-type semiconductor layer 301 and intrinsic semiconductor layer 302 may be configured to be about equal to each other in thickness. For example, each of the layers may be set to a film thickness of 300 nm to 1000 nm.

In order to form the intrinsic semiconductor layer 303 in FIG. 3H after the patterning of the n-type semiconductor layer 301 and intrinsic semiconductor layer 302 in FIG. 3G and thereby reduce the film thickness of the natural oxide film 401, hydrofluoric acid treatment may be applied to the intrinsic semiconductor layer 302. The hydrofluoric acid treatment can remove the natural oxide film 401 on the surface of the intrinsic semiconductor layer 302 and reduce contact resistance between the intrinsic semiconductor layer 302 and intrinsic semiconductor layer 303. As hydrofluoric acid, for example, buffered hydrofluoric acid or fluorinated ammonium is used. Instead of, or in addition to, the hydrofluoric acid treatment after patterning of the intrinsic semiconductor layer 302, hydrofluoric acid treatment may be applied to the intrinsic semiconductor layer 302 before the patterning.

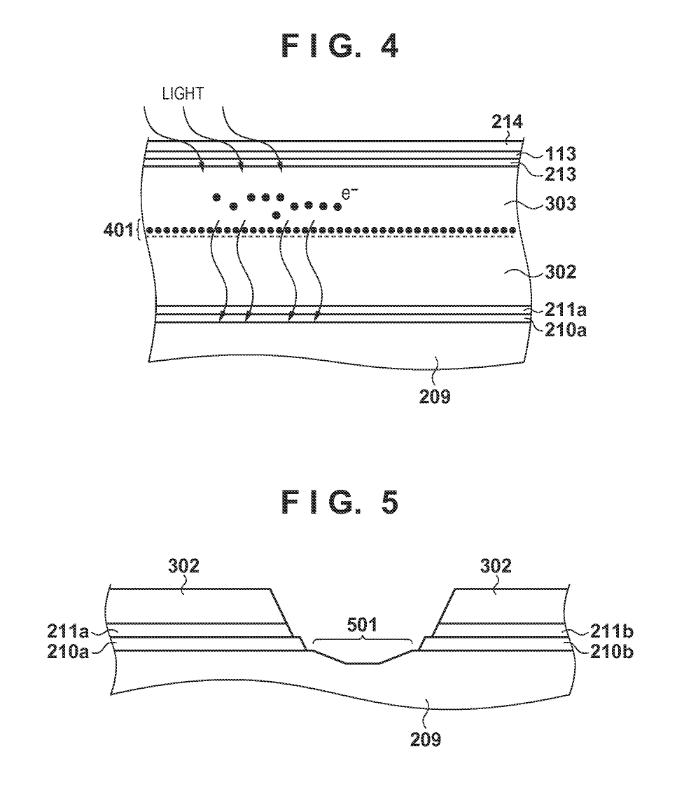

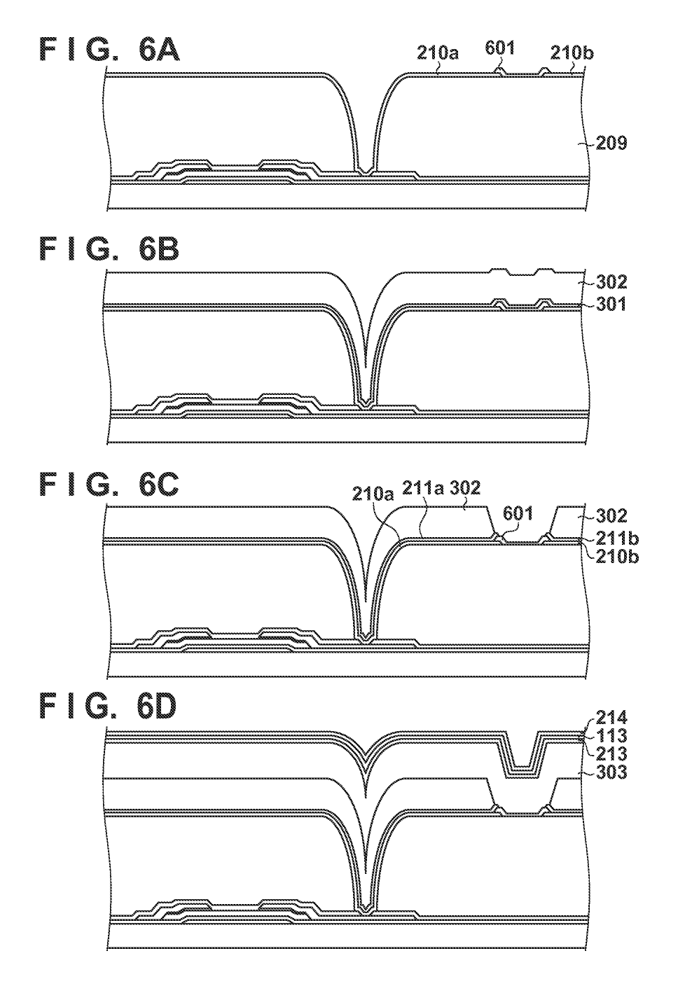

Next, a manufacturing method for a detection apparatus according to another embodiment of the present invention will be described with reference to FIGS. 5 and 6A to 6D. FIG. 5 is a diagram focusing on the vicinity of a region between the pixels PXa and PXb after patterning of the n-type semiconductor layer 301 and intrinsic semiconductor layer 302 in FIG. 3G in the embodiment described above. However, positional relationships among side faces of the discrete electrode 210a and 210b, n-type semiconductor layer 211a and 211b, and intrinsic semiconductor layer 302 differ from the embodiment described above. Specifically, whereas edges of the discrete electrodes 210a and 210b are covered by the n-type semiconductor layers 211a and 211b in the configuration of FIGS. 2A and 2B, the edges of the discrete electrodes 210a and 210b are not covered by the n-type semiconductor layers 211a and 211b in the configuration of FIG. 5.

When part of the intrinsic semiconductor layer 302 and part of the n-type semiconductor layer 301 are removed by etching, part 501 of the planarizing layer 209 located under the removed parts are also etched away. In this case, irregularities are produced in the planarizing layer 209 or impurities are mixed in the planarizing layer 209, reducing adhesion between the planarizing layer 209 and the intrinsic semiconductor layer 303 formed later or resulting in formation of leakage paths. Also, if the planarizing layer 209 is an organic insulating layer formed of an organic material, organic pollution can result.

Also, when the n-type semiconductor layers 211a and 211b are formed on the discrete electrodes 210a and 210b, an oxide on top faces of the discrete electrodes 210a and 210b will combine with the n-type semiconductor to form an oxide between the discrete electrodes 210a and 210b and the n-type semiconductor layers 211a and 211b. In this state, if hydrofluoric acid treatment is applied to remove the natural oxide film 401 from the intrinsic semiconductor layer 302, hydrofluoric acid will seep between the discrete electrodes 210a and 210b and the n-type semiconductor layers 211a and 211b, resulting in peeling of the n-type semiconductor layers 211a and 211b. According to the present embodiment, a protective film 601 described later is formed to prevent etching of the planarizing layer 209 and peeling of the n-type semiconductor layers 211a and 211b.

A manufacturing method for the detection apparatus according to the present embodiment will be described with reference to FIGS. 6A to 6D. First, components up to the discrete electrodes 210a and 210b are formed through processes similar to those in FIGS. 3A to 3E. Subsequently, as shown in FIG. 6A, the protective film 601 is formed at such locations as to cover that part of the planarizing layer 209 which is not covered by the discrete electrodes 210a and 210b as well as to cover the edges of the discrete electrodes 210a and 210b. A material which functions as an etching stopper layer when the n-type semiconductor layer 301 is etched and has hydrofluoric acid resistance is used for protective film 601. For example, an inorganic insulating layer is used as the protective film 601.

Next, as shown in FIG. 6B, the n-type semiconductor layer 301 and intrinsic semiconductor layer 302 are formed as in the case of FIG. 3F. Then, as shown in FIG. 6C, part of the n-type semiconductor layer 301 and part of the intrinsic semiconductor layer 302 are removed by etching as in the case of FIG. 3G. In this case, the protective film 601 functions as an etching stopper layer, preventing the planarizing layer 209 under the protective film 601 from being etched. In so doing, the n-type semiconductor layer 301 is etched by leaving out that part of the n-type semiconductor layer 301 which covers the edges of the protective film 601. Consequently, an interface between the discrete electrodes 210a and 210b and the n-type semiconductor layers 211a and 211b is covered and protected by the protective film 601.

Subsequently, hydrofluoric acid treatment may be applied to remove the natural oxide film formed on the surface of the intrinsic semiconductor layer 302. As shown in FIG. 6C, since the interface between the discrete electrodes 210a and 210b and the n-type semiconductor layers 211a and 211b is covered by the protective film 601, hydrofluoric acid will not seep through the interface, and consequently the n-type semiconductor layers 211a and 211b are kept from peeling off. Subsequently, as shown in FIG. 6D, the intrinsic semiconductor layer 303, p-type semiconductor layer 213, common electrode 113, and protective layer 214 are formed and the other components are formed to complete the detection apparatus, as in the case of FIGS. 3H and 3I.

In the example described above, the protective film 601 is formed at such locations as to cover that part of the planarizing layer 209 which is not covered by the discrete electrodes 210a and 210b as well as to cover the edges of the discrete electrodes 210a and 210b. However, if the protective film 601 is formed at least at such location as to cover the edges of the discrete electrodes 210a and 210b, hydrofluoric acid can be kept from seeping through the interface between the discrete electrodes 210a and 210b and the n-type semiconductor layers 211a and 211b.

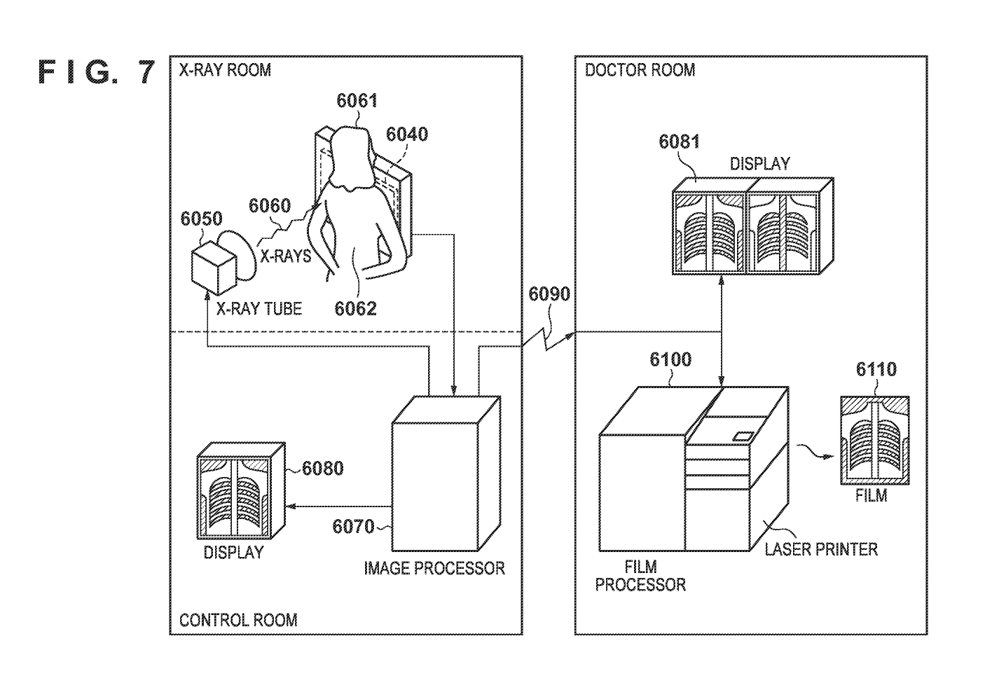

FIG. 7 is a diagram showing an example in which the radiation detection apparatus according to the present invention is applied to an x-ray diagnostic system (radiation detection system). Radiation, i.e., x-rays 6060, generated by an x-ray tube 6050 (radiation source) penetrates the chest 6062 of a subject or patient 6061 and enter a detection apparatus 6040, which is the detection apparatus according to the present invention with a scintillator provided in upper part. Here, the detection/conversion apparatus with a scintillator provided in the upper part makes up a radiation detection apparatus. The incident x-rays contains internal bodily information about the patient 6061. The scintillator emits light in response to the incident x-rays, and electrical information is obtained through photoelectric conversion of the emitted light. The electrical information is converted into a digital signal and then subjected to image processing by an image processor 6070, serving as a signal processing unit, to allow observation on a display 6080 serving as a display unit of a control room. Note that the radiation detection system includes at least the detection apparatus and a signal processing unit adapted to process a signal from the detection apparatus.

Also, this information can be transferred to a remote location by a transmission processing unit such as a telephone circuit 6090, displayed on a display 6081 serving as a display unit or saved on a recording unit such as an optical disk in a doctor room or the like at another location, allowing doctors at the remote location to carry out a diagnosis. Also, the information can be recorded by a film processor 6100 serving as a recording unit on a film 6110 serving as a recording medium.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-264741, filed Dec. 3, 2012 which is hereby incorporated by reference herein in its entirety.

What is claimed is:

1. A manufacturing method for a detection apparatus comprising:
a first deposition step of depositing a first impurity semiconductor layer and a first intrinsic semiconductor layer in this order on a plurality of first electrodes arranged in an array above a substrate;
a patterning step of patterning the first intrinsic semiconductor layer and the first impurity semiconductor layer and thereby dividing the first intrinsic semiconductor layer and the first impurity semiconductor layer so as to cover each of the plurality of first electrodes separately; and
a second deposition step of depositing a second intrinsic semiconductor layer on the patterned first intrinsic semiconductor layer.

2. The method according to claim 1, wherein a second impurity semiconductor layer is deposited on the second intrinsic semiconductor layer in the second deposition step.

3. The method according to claim 2, further comprising a second electrode forming step of forming a second electrode on the second impurity semiconductor layer.

4. The method according to claim 1, wherein in the first deposition step, after the first impurity semiconductor layer is deposited, the first intrinsic semiconductor layer is deposited without exposure to the atmosphere.

5. The method according to claim 1, wherein in the second deposition step, after the second intrinsic semiconductor layer is deposited, the second impurity semiconductor layer is deposited without exposure to the atmosphere.

6. The method according to claim 1, further comprising a step of removing an oxide film on a surface of the first intrinsic semiconductor layer by hydrofluoric acid treatment before the second deposition step.

7. The method according to claim 1, further comprising a step of forming a plurality of transistors above the substrate and forming an insulating layer configured to cover the plurality of transistors before forming the first electrodes, wherein
the plurality of first electrodes is formed above the insulating layer and electrically connected to the plurality of transistors.

8. The method according to claim 7, wherein:
the insulating layer is an organic insulating layer;
the method further comprises a step of forming an inorganic insulating layer configured to cover a part of the insulating layer which is not covered by the plurality of first electrodes before the first deposition step; and
the inorganic insulating layer functions as an etching stopper layer when the first impurity semiconductor layer is patterned.

9. The method according to claim 8, wherein:
the inorganic insulating layer is formed so as to cover edges of the plurality of first electrodes; and
in the patterning step, the first impurity semiconductor layer is patterned so as to cover edges of the inorganic insulating layer.

10. The method according to claim 1, wherein in the patterning step, the first impurity semiconductor layer is patterned so as to cover edges of the plurality of first electrodes.

11. The method according to claim 1, wherein the first intrinsic semiconductor layer and the second intrinsic semiconductor layer are equal to each other in thickness.
